(19) United States
(12) Patent Application Publication
(10) Pub. No.: US 2014/0079405 A1
(43) Pub. Date: Mar. 20, 2014

(54) OVERMOULDING METHOD AND OVERMOULDED ELECTRONIC DEVICE

(71) Applicant: Timothy D.F. Ford, Beaconsfield (CA)

(72) Inventor: Timothy D.F. Ford, Beaconsfield (CA)

(73) Assignee: THE FLEWELLING FORD FAMILY TRUST, BEACONSFIELD, QC (CA)

(21) Appl. No.: 14/112,380

(22) PCT Filed: Apr. 20, 2012
(86) PCT No.: PCT/CA12/50254

§ 371 Date: Dec. 4, 2013

(30) Foreign Application Priority Data
Apr. 21, 2011 (US) 61477690

(51) Int. Cl. H05K 3/28; H04B 10/40; H05K 5/06

(52) U.S. Cl. CPC H05K 3/284; H05K 5/065; H04B 10/40
USPC 398/135; 264/272.14

(57) ABSTRACT

An overmoulded electronic assembly wherein a moulded thermoplastic cover encapsulates and is in direct contact with the electronic components, printed circuit board and an antenna is disclosed. There also a disclosed a method of fabricating an overmoulded electronic assembly using an injection moulding machine and where the thermoplastic cover encapsulates and is in direct contact with the electronic components, printed circuit board and an antenna.

### FIELD OF THE INVENTION

The present invention relates to an overmoulding method and overmoulded electronic device.

### BACKGROUND TO THE INVENTION

Typically electronic assemblies comprising components attached to printed circuit boards using metal alloy solders are overmoulded, or potted, using low pressure compounds such as two part epoxies and the like, where the curable resin has good flow characteristics at low temperature. One drawback of potting is that a batch of epoxy once mixed has a limited time period during which it can be used. Additionally, the curing times are relatively long, thereby slowing production.

Electronic assemblies comprising components attached to printed circuit boards are also overmoulded using thermal setting plastics and the like. Indeed, use of thermal setting plastics can hermetically seal the electronics thereby limiting the egress of moisture, for example. Additionally, the outer shape of the mould can be selected to provide useful profiles to the outside of the finished component. However, during molding the temperatures of the plastic which comes into contact with the electronics must be controlled such that the solder is not melted, which would typically lead to the component being dislodged from the printed circuit board. Additionally, the cooling plastic develops forces which can twist, warp or crack the electronic assembly, which can have a negative effect on components, particular antennas which can be detuned through such forces and cease to work correctly. In order to address this, the prior art shows covering or potting the sensitive components with a first material, for example having a high flexibility or low curing temperature, or surrounding the sensitive components in a protective film or the like. One drawback of these methods is that the process requires two separate processing stages and is thereby complicated and relatively slow.

### SUMMARY OF THE INVENTION

In order to address the above and other drawbacks there is provided a method of fabricating an overmoulded electronic assembly using an injection moulding machine comprising a mould, the assembly comprising a plurality of electronic components attached to a printed circuit board using a solder having a melting temperature and at least one antenna. The method comprises drying a thermoplastic elastomeric compound in pellet form, the elastomeric compound having a melting temperature, heating the elastomeric compound to an injection temperature above the melting temperature, placing the electronic assembly in the mould, wherein the mould is maintained at a mould temperature of less than 32° C., injecting the molten elastomeric compound into the mould at a pressure greater than about 20 MPascals wherein the molten elastomeric compound comes into direct contact with the plurality of electronic components and the at least one antenna, maintaining the mould pressure for at least about 5 seconds, and removing the covered electronic assembly from the mould.

There is also disclosed an electronic device comprising an electronic assembly comprising a plurality of electronic components including transceiver, a pair of power inputs and an interface mounted on a printed circuit board using solder and an antenna operationally interconnected with the transceiver, a homogenous moulded thermoplastic cover encapsulating and in direct contact with the electronic components, the printed circuit board and the antenna and forming a battery compartment comprising a threaded opening configured for receiving a battery compartment cap, wherein the homogenous thermoplastic comes into direct contact with the electronic components, the printed circuit board and the antenna, the interface is exposed at an outer surface of the thermoplastic and further wherein the power inputs are exposed in the batter compartment, and a battery positioned within the battery compartment and interconnected between the pair of exposed power inputs, the cap hermetically sealing the battery compartment.

### BRIEF DESCRIPTION OF THE DRAWINGS

FIG. 1 provides a perspective view of an overmoulded electronic device in accordance with an illustrative embodiment of the present invention;

FIG. 2 provides a side cross-sectional view along II-II in FIG. 1;

FIG. 3 is a schematic diagram of the electronics of an overmoulded electronic device in accordance with an illustrative embodiment of the present invention;

FIG. 4 provides a partially cut away side plan view of an injection moulding setup in accordance with an illustrative embodiment of the present invention; and

FIGS. 5A and 5B provide respectfully top and bottom plan views of an electronic assembly in accordance with an illustrative embodiment of the present invention.

### DETAILED DESCRIPTION OF THE ILLUSTRATIVE EMBODIMENTS

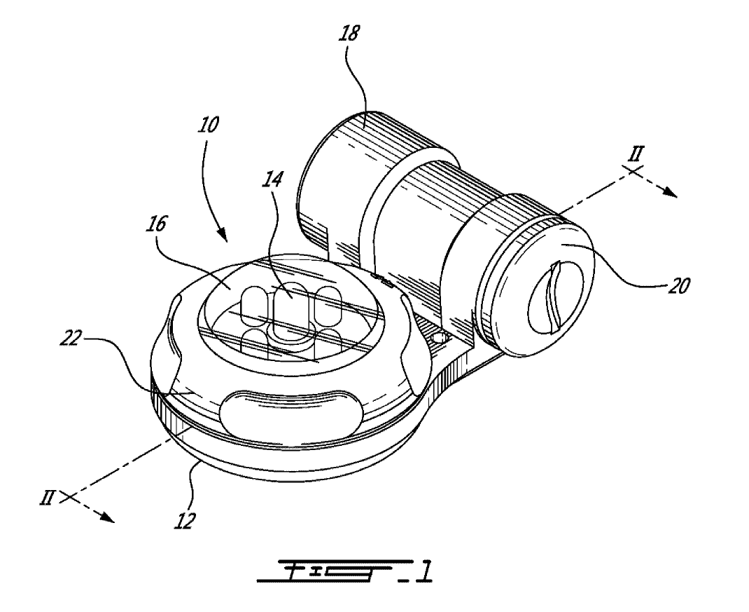

Referring now to FIG. 1, an overmoulded electronic device, generally referred to using the reference numeral 10, will now be described. The device is comprised of a housing 12 and a plurality of LEDs as in 14. The

LEDs as in 14 are encased within a translucent lens 16 and powered by a battery (not shown) held within a battery compartment 18 moulded into the plastic housing 12. The battery compartment 18 is sealed with a cap 20 which may be removed to facilitate replacement of the battery. In a particular embodiment a rotary switch 22 is provided encircling the translucent lens 16 allowing the user to select one between a plurality of operational modes, for example in order to select emission of a particular colour of light for emission by the LEDs as in 14 or a particular signaling sequence.

Still referring to FIG. 1, the housing 12 is fabricated from a resilient thermoplastic elastomer compound suitable for injection moulding, and can include ployurethanes and the like.

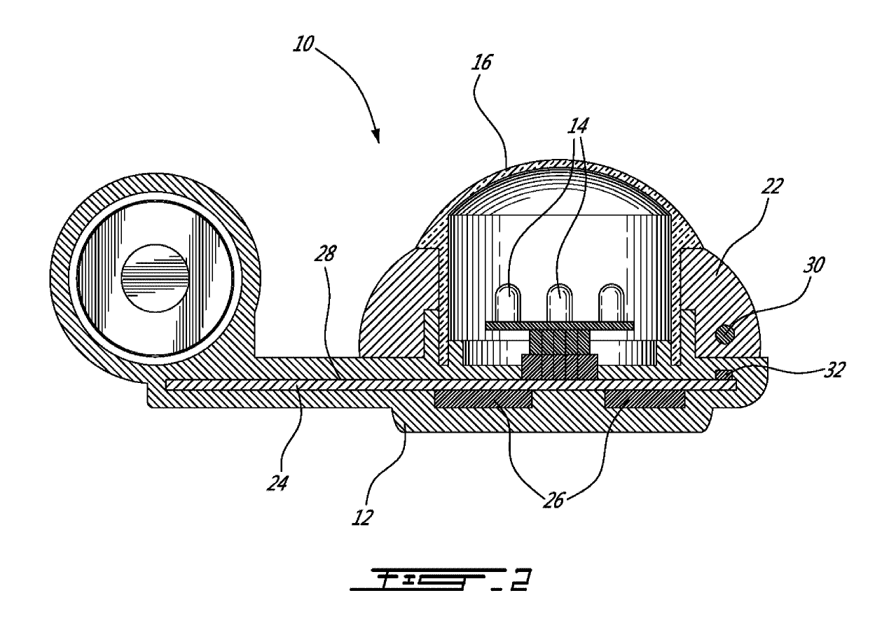

Referring now to FIG. 2, the device 10, the plastic housing 12 encapsulates an electronic assembly 24 comprised of a electronics 26 such as Surface Mounted Devices (SMDs), Bubble Gate Arrays (BGAs), antennas and the like soldered to a printed circuit board 28 which control the emission of light by one or more of the plurality of LEDs as in 14 and in accordance with the position of the rotary switch 22. In this regard, the rotary switch 22 comprises a small magnet 30 imbedded therein which illustratively selectively interacts with a plurality of switches as in 32, which also form part of the electronic assembly 24, as the rotary switch 22 is rotated about the translucent lens.

Still referring to FIG. 2, and as will be discussed in more detail below, the plastic housing 12 is formed using a “one shot” injection moulding process such that the plastic housing 12 encapsulates the electronic assembly 24, coming into direct contact with the electronics 26, in particular the antennas.

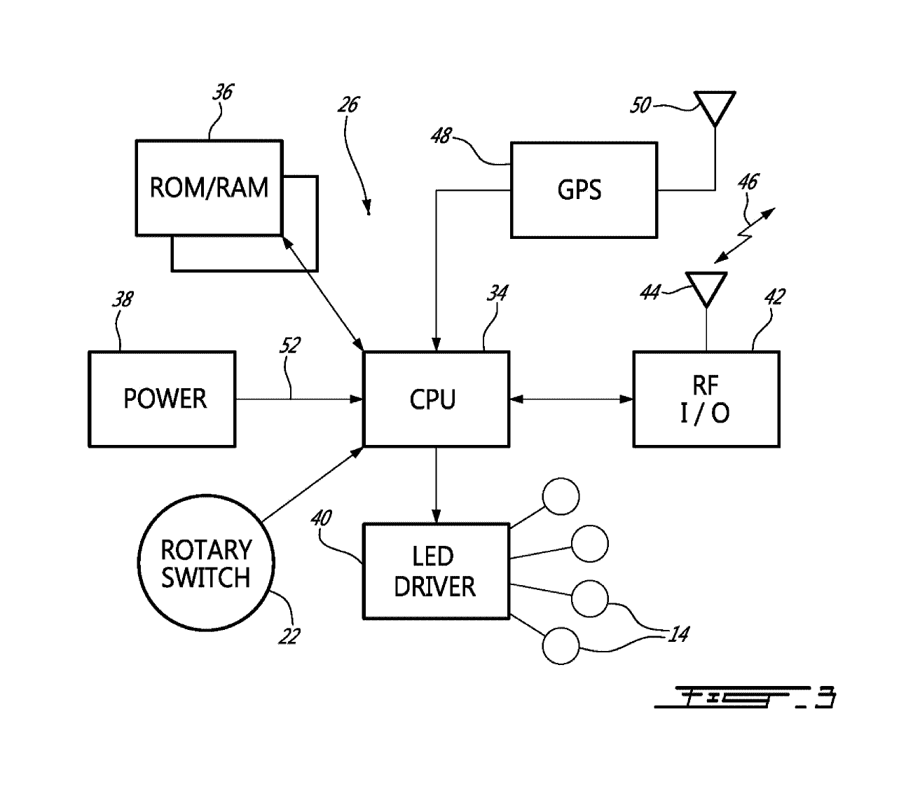

Referring now to FIG. 3, the electronics 26 illustratively comprise a Central Processing Unit (CPU) or other controller 34, ROM/RAM or flash memory or the like 36 for storing instructions and configuration data, a power source 38 such as a battery or the like as well as conditioning electronics (not shown) for ensuring that the requisite voltages and the like are provided to the electronics, an LED driver 40 for driving the one or more LEDS as in 14, an RF transceiver interface 42 comprising an R/F antenna 44 for sending and receiving data and instructions via a wireless connection 46 and a GPS module 48 and associated GPS antenna 50 for receiving location based data as well as a universal time signal, if so required. In operation, the CPU 34, under control of instructions stored in the ROM/RAM 36, user inputs received via the rotary switch 22 or the R/F interface 42, drives the one or more LEDs as in 14 such that they emit light, or flash, according to a predetermined sequence, for example the well known SOS 3 dot, 3 dash, 3 dot sequence. In a particular embodiment, orientation of the battery in the battery compartment (reference 18 in FIG. 1) can also be provided as an input 52 to the CPU 34, for example to change the mode of operation or the like.

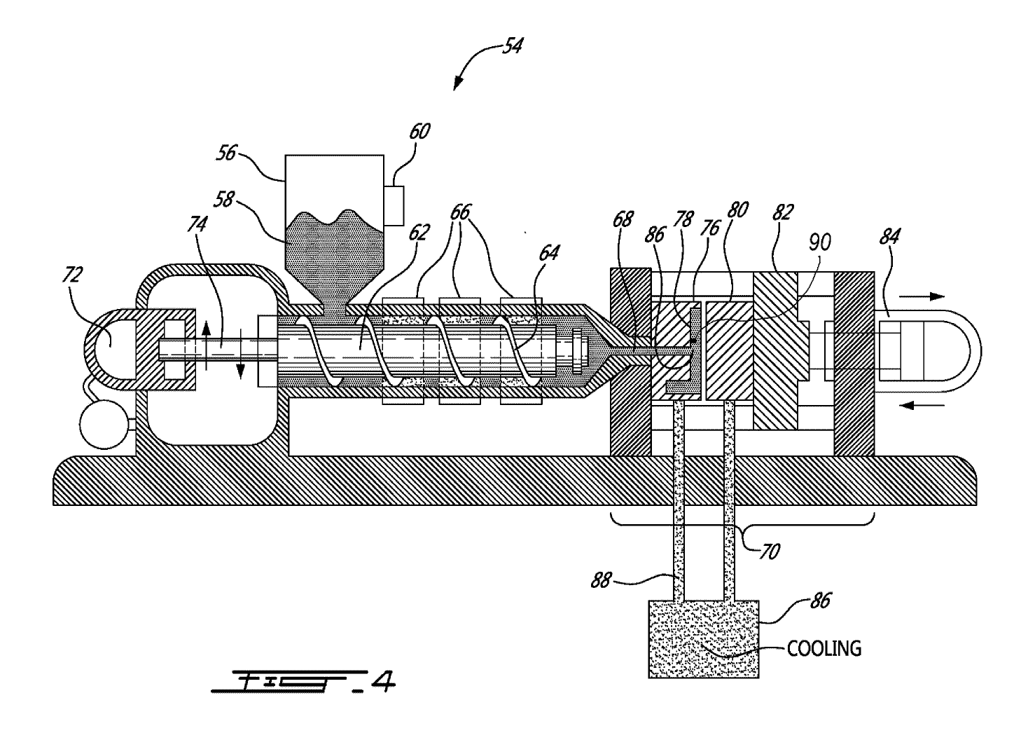

Referring now to FIG. 4, in order to fabricate the device of the present invention, an injection moulding setup, generally referred to using the reference numeral 54, is used. The injection moulding setup 54 comprises a hopper 56 for holding pellets of a thermoplastic compound 58. Illustratively, the thermosetting compound is a thermoplastic polyurethane elastomer such as ABS or PVC or the like. As the thermoplastic compound 58 is typically hydroscopic, the hopper 56 is equipped with a dryer 60 for maintaining the pellets 58 at a predetermined humidity level, preferably below 0.02%. The hopper feeds the pellets into the barrel 62 of the injection moulding setup 54 which has arranged therein a reciprocating screw 64 for conveying the thermoplastic compound 58 through a series of heating elements 66 and towards a nozzle 68 and the mould 70. The barrel 62 and reciprocating screw 64 are rotated using an hydraulic motor 72 via a shaft 74.

Still referring to FIG. 4, the mould 70 is comprised of a fixed part 76 comprising a mould cavity 78 and a moveable part 80. The moveable part 80 is attached to a platen 82 which can be moved away and towards the fixed part 76 under control of a hydraulic piston 84 or the like, which is able to maintain contact between the moveable part 80 and the fixed part 76 at high pressure. Appropriate controls (not shown) are provided allowing an operator to open and close the mould 70 in order to remove moulded items therefrom (also not shown).

Still referring to FIG. 4, attached to the fixed part 76 and/or the moveable part 80 is a cooling system 86 which circulates a coolant 88 through the mould 70 in order to maintain it at a relatively cool temperature, illustratively at or below 32° C.

Still referring to FIG. 4, the injection moulding setup 54 comprises a control panel (not shown) which allows the user to configure the injection moulding setup 54 in terms of (1) initial temperature of the thermoplastic compound 58, speed and duration of delivery of the thermoplastic compound 58 into the mould 70, pressure with which the thermoplastic compound 58 is injected into the mould cavity 78, pressure of the mould cavity during subsequent curing and the duration the mould 70 remains closed as well as the temperature at which the mould 70 is to be maintained by the coolant 88 during curing. Careful selection of a suitable thermoplastic compound 58, injection temperatures, mould pressures and the like as well as durations of each of the process steps is necessary to ensure minimal warping and cracking during curing and subsequent removal of the device from the mould cavity 78. In particular, warping of the thermoplastic compound 58 during curing can detune the antennas thereby reducing their effectiveness or rendering the device non-usable. Additionally, the design of the mould 70 and the mould cavity 78, in particular the origin and direction (or directions) in which the thermoplastic compound 58 flows into the mould cavity 78.

Still referring to FIG. 4, pressures during introduction of the thermoplastic compound 58 are typically between 3000-6000 psi and initial temperatures of the thermoplastic compound 58 are typically above the melting point of the solder used to secure the electronics to the printed circuit board (that is, typically above 408° F.). The mould 70 is maintained closed for a sufficient amount of time only to ensure proper setting, typically between 5 to 15 seconds.

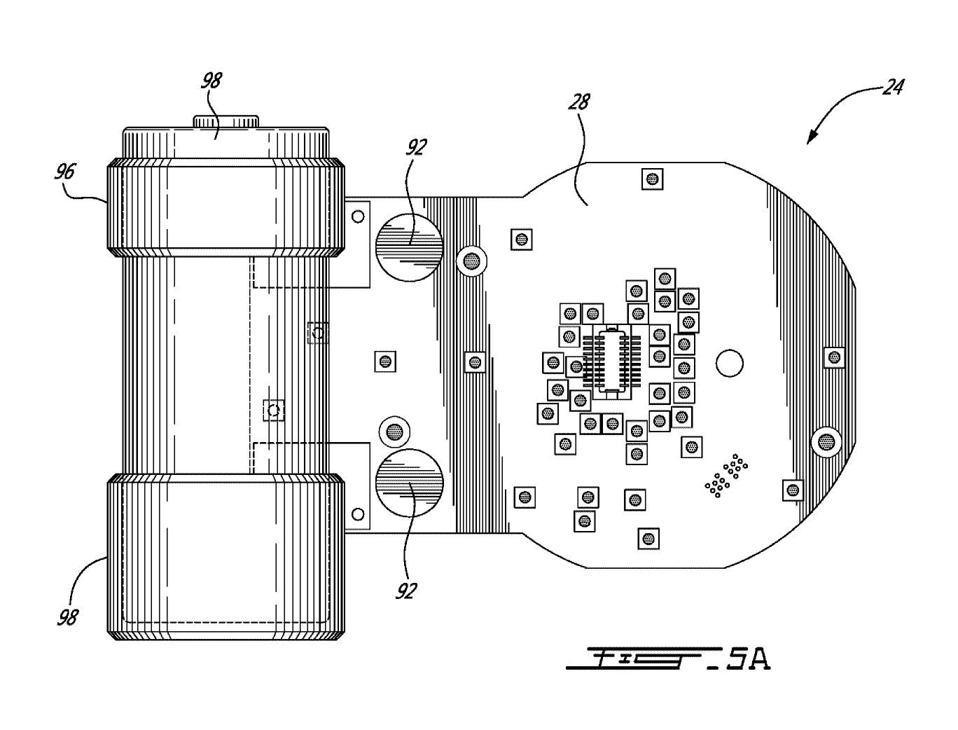

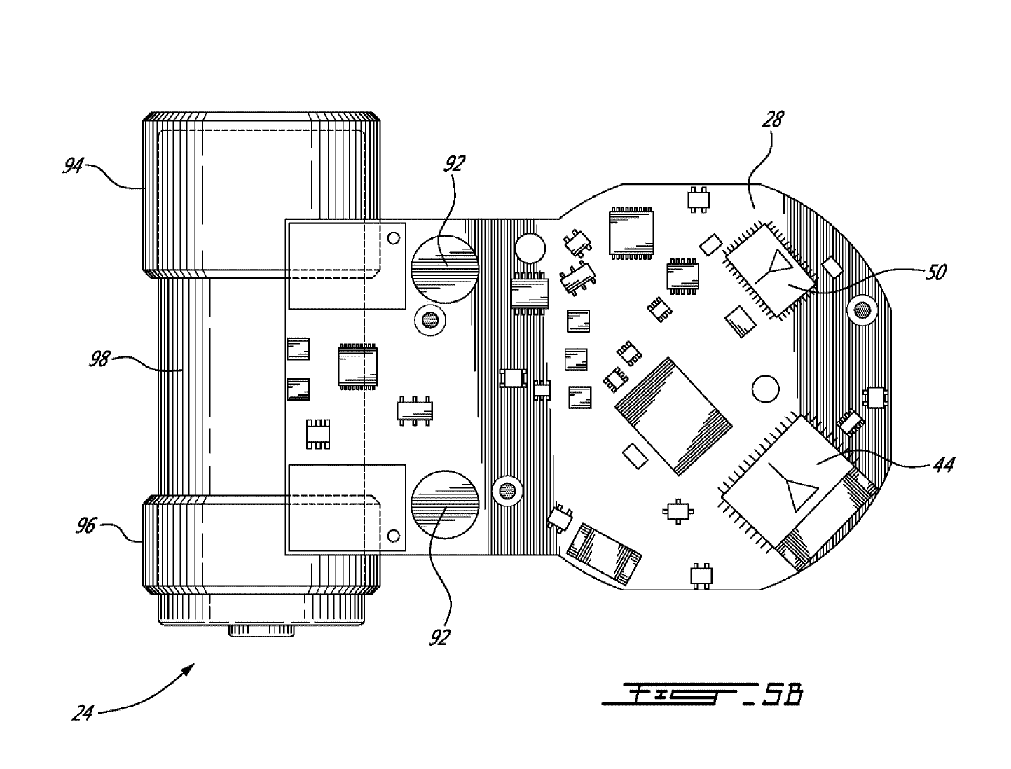

Referring now to FIGS. 5A and 5B in addition to FIG. 4, in operation the mould 70 is opened by moving the moveable part 80 away from the fixed part 76. The electronic assembly 24 is then inserted into the mould cavity 78 and held in place by at least one pin 90, each of which mates with a corresponding pin receiving hole 92 moulded in the printed circuit board 28 in a light friction fit. The mould 70 is closed by the operator by activating the hydraulic piston 84 thereby moving the moveable part 80 towards the fixed part 76, thereby enclosing the electronic assembly 24. Once the mould is closed the reciprocating screw 64 advances a single shot of molten thermoplastic compound 58 into the mould which encapsulates the electronic assembly 24 coming into contact with the printed circuit board 28 and the electronics 26, in particular the RF antenna 44 and/ or the GPS antenna 50 which form part of the electronics 26. Pressure is maintained on the mould for a predetermined amount of time, typically between 5 to 10 seconds, while the temperature of the mould 70 is maintained at a constant temperature as discussed above.

Still referring to FIGS. 5A and 5B, in order to provide subsequent contact between a power source such as a battery of the like, the electronic assembly 24 comprises a first brass contact 94 and a second brass contact 96 which are conductively attached to the printed circuit board 28 using a solder or the like. In order to ensure that the thermoplastic compound 58 does not effect the contact between a battery and contacts, prior to moulding a snug-fitting battery sized plug 98 is inserted through the second brass contact 96, which is ring-like and comprises a threaded inner surface (not shown) into the first brass contact 94, which is cup shaped until it butts up against an inside end of the first brass contact 94. The plug is removed once moulding has been completed. Of note is that the thread on the inner surface of the second brass contact 96 is for receiving, during use of the device, the battery compartment cap (reference 20 in FIG. 1).

Once the thermoplastic compound 58 has adequately set the mould 70 is opened by moving the moveable part 80 away from the fixed part 76 and the over-moulded electronic device 10 removed from the mould 70.

The overmoulded device 10 so fabricated is resilient to shocks, vibrations and with the cap placed on the battery compartment (respectively references 20 and 18 in FIG. 1), water.

The adding of elastomers to the thermoplastic compound 58 has the additional advantage that the texture of the external surface of the over-moulded electronic device 10 can be modified to provide a more pleasing look and feel.

While this invention has been described with reference to the illustrative embodiments, this description is not intended to be construed to a limiting sense. Various modifications or combinations of the illustrative embodiment of the invention will be apparent to persons skilled in the art upon reference to the description. It is therefore intended that the described invention encompass any such modifications or embodiments.

1. A method of fabricating an overmoulded electronic assembly using an injection moulding machine comprising a mould, the assembly comprising a plurality of electronic components attached to a printed circuit board using a solder having a melting temperature and at least one antenna, the method comprising:
drying a thermoplastic elastomeric compound in pellet form, said elastomeric compound having a melting temperature;
heating said elastomeric compound to an injection temperature above said melting temperature;
placing the electronic assembly in the mould, wherein the mould is maintained at a mould temperature of less than 32° C.;
injecting said molten elastomeric compound into the mould at a pressure greater than about 20 MPascals wherein said molten elastomeric compound comes into direct contact with the plurality of electronic components and the at least one antenna;
maintaining said mould pressure for at least about 5 seconds; and
removing said covered electronic assembly from the mould.

2. The method of claim 1, wherein said molten elastomeric compound is injected into the mould at a pressure of less than about 40 MPascals.

3. The method of claim 2, wherein said molten elastomeric compound is injected into the mould at a pressure of about 35 MPascals.

4. The method of claim 1, wherein said mould pressure is maintained for between 5 to 15 seconds.

5. The method of claim 1, wherein said mould pressure is maintained for about 10 seconds.

6. The method of claim 1, wherein said injection temperature is at least above a solder melting temperature.

7. The method of claim 1, wherein said injection temperature is at least above 408° F.

8. The method of claim 1, wherein said thermoplastic elastomeric compound in pellet form is dried such that it contains less than 0.02% humidity.

9. The method of claim 1, wherein a single shot of said elastomeric compound is injected into the mould.

10. An electronic device comprising:
an electronic assembly comprising a plurality of electronic components including transceiver, a pair of power inputs and an interface mounted on a printed circuit board using solder and an antenna operationally interconnected with said transceiver;
a homogenous moulded thermoplastic cover encapsulating and in direct contact with said electronic components, said printed circuit board and said antenna and forming a battery compartment comprising a threaded opening configured for receiving a battery compartment cap, wherein said homogenous thermoplastic comes into direct contact with the electronic components, said printed circuit board and said antenna, said interface is exposed at an outer surface of said thermoplastic and further wherein said power inputs are exposed in said batter compartment; and
a battery positioned within said battery compartment and interconnected between said pair of exposed power inputs, said cap hermetically sealing said battery compartment.

11. The electronic device of claim 10, further comprising an LED assembly comprising a plurality of LEDs, wherein said LED assembly is interconnected with said electronic components via said exposed interface and a translucent lens covering said LED assembly and bonded to said cover to form a hermetic seal.
